(19) United States
(12) Patent Application Publication
(10) Pub. No.: US 2015/0214116 A1
(43) Pub. Date: Jul. 30, 2015

(54) LOW LEAKAGE PMOS TRANSISTOR

(71) Applicant: GLOBALFOUNDRIES Inc., Grand Cayman (KY)

(72) Inventors: Peter Javorka, Radeburg (DE); Juergen Faul, Radebeul (DE); Jan Hoentschel, Dresden (DE); Stefan Flachowsky, Dresden (DE); Ralf Richter, Radebeul (DE)

(73) Assignee: GLOBALFOUNDRIES Inc., Grand Cayman (KY)

(21) Appl. No.: 14/165,107

(22) Filed: Jan. 27, 2014

(51) Int. Cl. H01L 21/8238; H01L 21/266; H01L 29/78; H01L 29/161; H01L 27/092; H01L 21/324; H01L 21/02

(52) U.S. Cl. CPC H01L 21/823807; H01L 21/823814; H01L 21/324; H01L 21/266; H01L 21/02532; H01L 29/161; H01L 27/0922; H01L 29/7842

(57) ABSTRACT

A method of forming a semiconductor device is provided including the steps of forming first and second PMOS transistor devices, wherein the first PMOS transistor devices are low, standard or high voltage threshold transistor devices and the second PMOS transistor devices are super high voltage threshold transistor devices, and wherein forming the first PMOS transistor devices includes implanting dopants to form source and drain junctions of the first PMOS transistor devices and performing a thermal anneal of the first PMOS transistor devices after implanting the dopants, and forming the second PMOS transistor devices includes implanting dopants to form source and drain junctions of the second PMOS transistor devices after performing the thermal anneal of the first PMOS transistor devices.

### BACKGROUND OF THE INVENTION

1. Field of the Invention

Generally, the present disclosure relates to the field of integrated circuits and semiconductor devices, and, more particularly, to the manufacture of PMOS transistors with low leakage currents and, in particular, super high voltage thresholds.

2. Description of the Related Art

The fabrication of advanced integrated circuits, such as CPUs, storage devices, ASICs (application specific integrated circuits) and the like, requires the formation of a large number of circuit elements on a given chip area according to a specified circuit layout. In a wide variety of electronic circuits, field effect transistors represent one important type of circuit element that substantially determines performance of the integrated circuits. Generally, a plurality of process technologies are currently practiced for forming field effect transistors, wherein, for many types of complex circuitry, MOS technology is currently one of the most promising approaches due to the superior characteristics in view of operating speed and/or power consumption and/or cost efficiency. During the fabrication of complex integrated circuits using, for instance, MOS technology, millions of transistors, e.g., N-channel transistors and/or P-channel transistors, are formed on a substrate including a crystalline semiconductor layer.

A field effect transistor, irrespective of whether an N-channel transistor or a P-channel transistor is considered, typically comprises so-called PN junctions that are formed by an interface of highly doped regions, referred to as drain and source regions, with a slightly doped or non-doped region, such as a channel region, disposed between the highly doped regions. In a field effect transistor, the conductivity of the channel region, i.e., the drive current capability of the conductive channel, is controlled by a gate electrode formed adjacent to the channel region and separated therefrom by a thin insulating layer. The conductivity of the channel region, upon formation of a conductive channel due to the application of an appropriate control voltage to the gate electrode, depends on, among other things, the dopant concentration, the mobility of the charge carriers and, for a given extension of the channel region in the transistor width direction, the distance between the source and drain regions, which is also referred to as channel length. Hence, in combination with the capability of rapidly creating a conductive channel below the insulating layer upon application of the control voltage to the gate electrode, the conductivity of the channel region substantially affects the performance of MOS transistors. Thus, as the speed of creating the channel, which depends on the conductivity of the gate electrode, and the channel resistivity substantially determine the transistor characteristics, the scaling of the channel length is a dominant design criterion for accomplishing an increase in the operating speed of the integrated circuits.

In sophisticated transistor elements, a plurality of features finally determine the overall performance of the transistor, wherein a complex mutual interaction of these factors may be difficult to assess such that a wide variety of performance variations may be observed for a given basic transistor configuration. For example, the conductivity of doped silicon-based semiconductor regions may be increased by providing a metal silicide therein in order to reduce overall sheet resistance and contact resistivity. For example, the drain and source regions may receive a metal silicide, such as nickel silicide, nickel platinum silicide and the like, thereby reducing the overall series resistance of the conductive path between the drain and source terminals and the intermediate channel region. Similarly, a metal silicide may typically be formed in the gate electrode, which may comprise polysilicon material, thereby enhancing conductivity and thus reducing signal propagation delay. Although an increased amount of metal silicide in the gate electrode may per se be desirable in view of reducing the overall resistance thereof, a substantially complete silicidation (salicidation) of the polycrystalline silicon material down to the gate dielectric material may not be desirable in view of voltage threshold adjustment of the corresponding transistor element. It may, therefore, be desirable to maintain a certain portion of the doped polysilicon material in direct contact with the gate dielectric material so as to provide well-defined electronic characteristics in the channel region, so as to avoid significant threshold variations, which may be caused by a substantially full silicidation within portions of the gate electrode.

On the other hand, in some aggressively scaled transistor elements, which may have channel lengths on the order of approximately 10-20 nm or less, gate structures that include a so-called high-k dielectric gate insulation layer and one or more metal layers that function as the gate electrode have been implemented that provide significantly enhanced operational characteristics over the heretofore more traditional silicon dioxide/polysilicon gate structure configurations.

In principle, there are two well-known processing methods for forming a planar or 3D transistor with a high-k/metal gate (HKMG) structure: (1) the so-called “gate last” or “replacement gate” technique; and (2) the so-called “gate first” technique. In the replacement gate technique, a so-called “dummy” or sacrificial gate structure is initially formed and remains in place as many process operations are performed to form the device, e.g., the formation of doped source/drain regions, performing an anneal process to repair damage to the substrate caused by the ion implantation processes and to activate the implanted dopant materials. At some point in the process flow, the sacrificial gate structure is removed to define a gate cavity where the final HKMG gate structure for the device is formed. In general, using the “gate first” technique involves forming a stack of layers of material across the substrate, wherein the stack of materials includes a high-k gate insulation layer, one or more metal layers, a layer of polysilicon and a protective cap layer, for example, silicon nitride. Thereafter, one or more etching processes are performed to pattern the stack of materials to thereby define the basic gate structures for the transistor devices.

In addition, an efficient mechanism for increasing the charge carrier mobility is the modification of the lattice structure in the channel region, for instance by creating tensile or compressive stress in the vicinity of the channel region so as to produce a corresponding strain in the channel region, which results in a modified mobility for electrons and holes, respectively. For example, creating uniaxial tensile strain in the channel region along the channel length direction for a standard crystallographic orientation increases the mobility of electrons, which, in turn, may directly translate into a corresponding increase in the conductivity. On the other hand, uniaxial compressive strain in the channel region for the same configuration as above may increase the mobility of holes, thereby providing the potential for enhancing the performance of P-type transistors.

In some approaches, external stress created by, for instance, permanent overlaying layers, spacer elements and the like, is used in an attempt to create a desired strain within the channel region. In still a further approach, a substantially amorphized region may be formed adjacent to the gate electrode at an intermediate manufacturing stage, which may then be re-crystallized in the presence of a rigid layer formed above the transistor area. During the anneal process for re-crystallizing the lattice, the growth of the crystal will occur under stress conditions created by the overlayer and result in a tensilely strained crystal. After the re-crystallization, the sacrificial stress layer may be removed, wherein, nevertheless, a certain amount of strain may be “conserved” in the re-grown lattice portion. This effect is generally known as stress memorization. In other approaches, a strained silicon base material may be provided by, for instance, growing silicon on a relaxed silicon/germanium (Si/Ge) alloy, which has a greater lattice constant compared to natural silicon, thereby resulting in a bi-axial tensile strain in the re-grown silicon material, which may thus enable enhancement of P-channel transistors and N-channel transistor due to the bi-axial nature of the strain. Another efficient strain-inducing mechanism available for PMOS transistors comprises the formation of embedded strained silicon/germanium material.

In the context of the above-described examples, five threshold voltage options (flavors) are available, in principle: super low, low, standard, high and super high, all of which are defined by respective dopants and of relevance, particularly, in the context of 28 nm technology. In particular, for super high voltage thresholds (for example, VT of some 350 mV), low current leakage has to be observed.

However, Gate Induced Drain Leakage (GIDL) poses a severe problem for low leakage super high VT PMOS transistors. GIDL is caused by the high field effect in the drain junction of a MOS transistor. When the gate is biased to form an accumulation layer at the silicon surface, the silicon surface under the gate has almost the same potential as the P-type substrate. Due to presence of accumulated holes at the surface, the surface behaves like a P-region that is more heavily doped than the substrate. This causes the depletion layer at the surface to be much narrower than elsewhere. The narrowing of depletion layer at or near the surface causes field crowding or an increase in the local electric field. Thereby, the high field effect is significantly enhanced. When the negative gate bias is large (i.e., gate at zero or negative and drain at VDD), the n+ drain region under the gate can be depleted and even inverted. This causes even more field crowding and the peak field increases, resulting in a dramatic increase of high field effects, such as avalanche multiplication and band-to-band tunneling of charge carriers. As a result of all these effects, minority carriers are emitted in the drain region underneath the gate. Since the substrate is at a lower potential for minority carriers, the minority carriers that have been accumulated or formed at the drain depletion region underneath the gate are swept laterally to the substrate, thereby resulting in severe GIDL heavily affecting the performance of the transistor device.

In view of the situation described above, the present disclosure provides techniques that allow for the manufacture of low leakage, PFETs in particular, super high voltage threshold PMOS transistors no longer suffering from GIDL limitations.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

An illustrative method of forming a semiconductor device includes the steps of forming first and second PMOS transistor devices, wherein the first PMOS transistor devices are low, standard or high voltage threshold (threshold voltage) transistor devices and the second PMOS transistor devices are super high voltage threshold transistor devices. Moreover, forming the first PMOS transistor devices includes implanting dopants to form source and drain junctions of the first PMOS transistor devices and performing a thermal anneal of the first PMOS transistor devices after implanting the dopants. Forming the second PMOS transistor devices includes implanting dopants to form source and drain junctions of the second PMOS transistor devices after performing the thermal anneal of the first PMOS transistor devices.

As used herein, low voltage threshold refers to a voltage threshold of 80-160 mV, standard voltage threshold refers to a voltage threshold of more than 160 mV and at most 240 mV, high voltage threshold refers to a voltage threshold of more than 240 mV and at most 320 mV, and super high voltage threshold refers to a voltage threshold of more than 320 mV and at most 400 mV. For example, a low voltage threshold is given by about 120 mV with a leakage current of 200 nA/μm, a standard voltage threshold is given by about 200 mV with a leakage current of 15 nA/μm, a high voltage threshold is given by about 280 mV with a leakage current of 2 nA/μm, and a super high voltage threshold is given by 360 mV with a leakage current of 0.2 nA/μm. Voltage thresholds (threshold voltages) are given in absolute values.

Another illustrative method of forming a semiconductor device includes the steps of forming a low, standard or high voltage threshold PMOS transistor device, forming a super high voltage threshold PMOS transistor device, and forming an NMOS transistor device separated by an isolation region from the super high voltage threshold PMOS transistor device. Forming the low, standard or high voltage threshold PMOS transistor device includes forming a first gate electrode over a first region of a semiconductor substrate, implanting first dopants to form source and drain junctions in the first region and performing an anneal treatment to activate the first dopants. Forming the super high voltage threshold PMOS transistor device includes forming a second gate electrode over a second region of the semiconductor substrate and implanting second dopants to form source and drain junctions in the second region after completion of the anneal treatment performed to activate the first dopants.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1f illustrate processing stages according to an example of a method of forming a low leakage super high voltage threshold PMOS transistor device according to the present invention;

FIG. 2 illustrates a layer stack that might be comprised in the configuration shown in FIG. 1a and comprises a channel SiGe alloy layer;

FIG. 3 illustrates a comparison of GIDL limitations according to the art and an example of the present invention; and

FIG. 4 illustrates a comparison of leakage current limitations according to the art and an example of the present invention.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

As will be readily apparent to those skilled in the art upon a complete reading of the present application, the present methods are applicable to a variety of technologies, for example, PMOS devices in the context of 35 or 28 nm technologies, and is readily applicable to a variety of devices, including, but not limited to, logic devices, memory devices, etc.

The present disclosure relates to a method of forming a low leakage PMOS transistor, in particular, a super high voltage threshold (SHVT) PMOS transistor with significantly reduced Gate Induced Drain Leakage (GIDL) as compared to the art. In the context of SHVT PMOS transistors, the demand for low leakage currents has to be observed. The reduction of the GIDL while observing the necessity for low leakage currents is achieved by performing doping with SHVT implants after PMOS stabilization anneal. The method will be illustrated by the following description making reference to the accompanied figures.

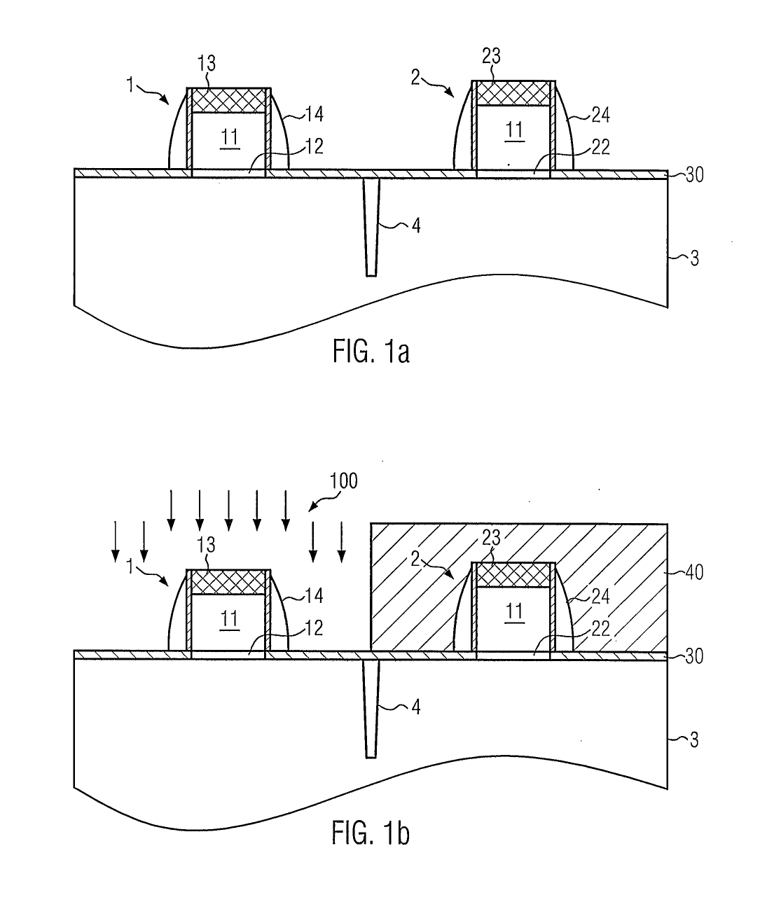

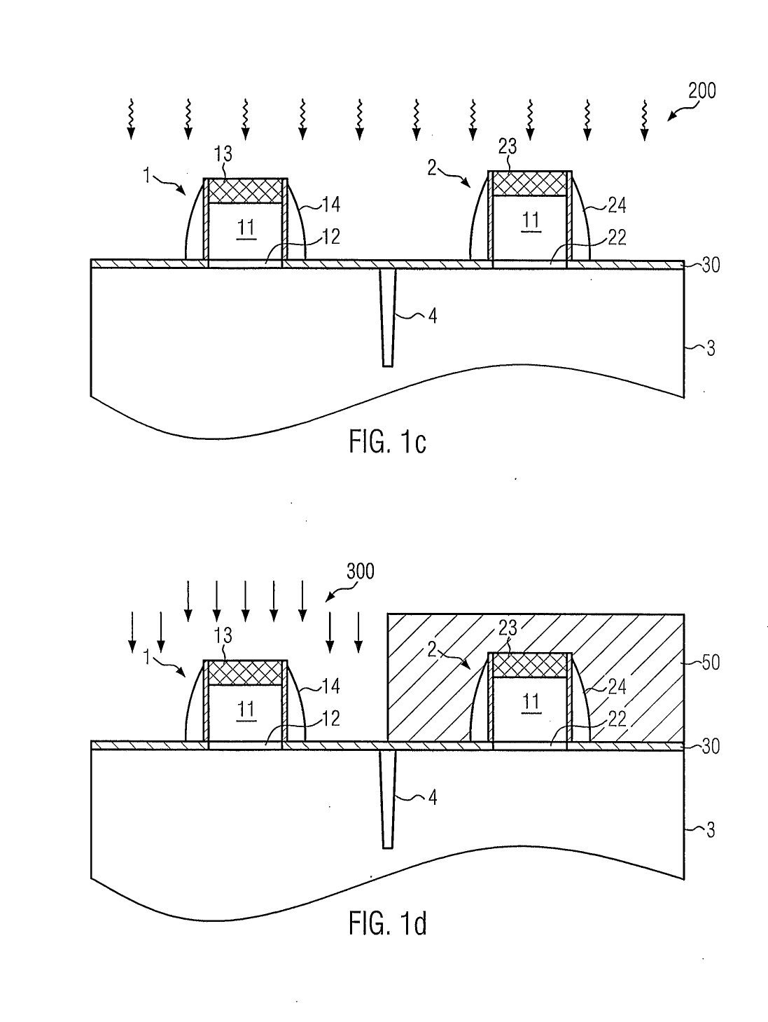

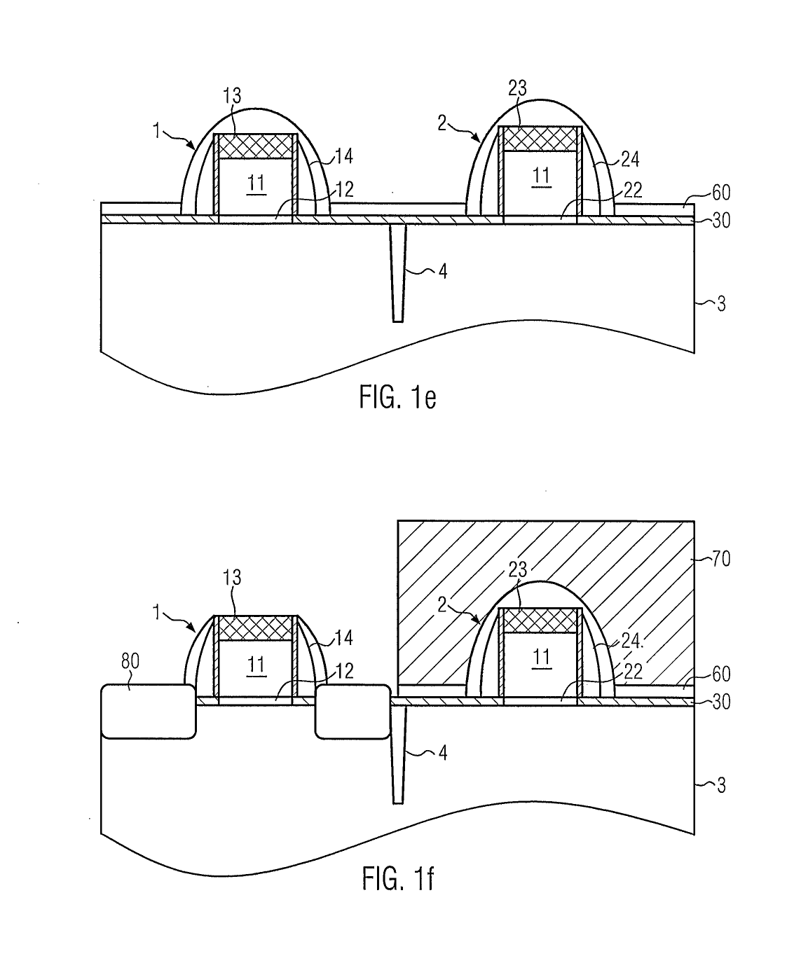

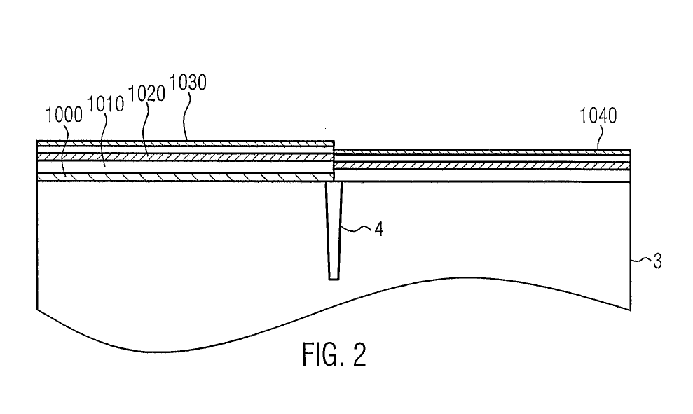

A starting point for illustrating the inventive method is shown in FIG. 1a. FIG. 1a shows a PMOS transistor device (PFET) 1 and an NMOS transistor device (NFET) 2 of a wafer both formed on a semiconductor substrate 3. The semiconductor substrate 3 may comprise a semiconductor layer, which in turn may be comprised of any appropriate semiconductor material, such as silicon, silicon/germanium, silicon/carbon, other II-VI or III-V semiconductor compounds and the like. The semiconductor layer may comprise a significant amount of silicon due to the fact that semiconductor devices of high integration density may be formed in volume production on the basis of silicon due to the enhanced availability and the well-established process techniques developed over the last decades. However, any other appropriate semiconductor materials may be used, for instance, a silicon-based material containing other iso-electronic components, such as germanium, carbon and the like. Furthermore, the substrate and the semiconductor layer may define an SOI (silicon-on-insulator) configuration.

The semiconductor substrate 3 may be a silicon substrate, in particular, a single crystal silicon substrate. Other materials may be used to form the semiconductor substrate such as, for example, germanium, silicon/germanium, gallium phosphate, gallium arsenide, etc.

The active region of the semiconductor substrate where the PMOS transistor device 1 is formed is separated from the active region of the semiconductor substrate where the NMOS transistor device 2 is formed by a shallow trench isolation (STI) 4. The PMOS transistor device 1 comprises a gate electrode 11 and the NMOS transistor device 2 comprises a gate electrode 21. The STI 4 particularly separates doped channel regions formed in the substrate 3 below gate electrode 11 and gate electrode 21. Gate electrode 11 is formed on a gate dielectric 12 and covered by a cap layer 13 and gate electrode 21 is formed on a gate dielectric 22 and covered by a cap layer 23. The cap layers 13 and 23 may be formed of a nitride material. Alternatively, the cap layers 13 and 23 may be formed from a low temperature oxide mask layer deposited at some 400° C.

The gate electrodes 11 and 21 may consist of or comprise polysilicon or metal and polysilicon layers, for example. The gate dielectrics 12 and 22 may be provided in the form of a silicon oxide-based material, such as a silicon oxynitride and the like, followed by a high-k dielectric material, such as hafnium oxide, hafnium silicon oxide and the like. Particularly for transistor devices with very short channel lengths, for example, of some 10 nm, gate structures with high-k dielectric gate insulating layers and one or more metal layers functioning as a gate electrode 11 and 21 may be provided that show improved operational characteristics as compared to conventional silicon dioxide/polysilicon gates. The high-k insulation layers may include or consist of tantalum oxide, hafnium oxide, titanium oxide or hafnium silicates, for example. Furthermore, in the HKMG technology, a thin “work function metal” layer (not shown in FIG. 1a) may be inserted between the high-k dielectric (12 and 22) and the gate material (11 and 22) placed above the high-k dielectric (12 and 22). The voltage threshold may thus be adjusted by varying the thickness of the metal layer.

The gate metal layer may comprise, for example, tantalum (Ta), tungsten (W), titanium nitride (TiN) or tantalum nitride (TaN). On the other hand, the work function metal layer may comprise metals such as aluminum and lanthanum. Work function metals may also be included in the gate metal layer. In addition, a channel SiGe alloy layer may be formed below the gate dielectric 12 of the PMOS transistor device 1. The channel SiGe alloy layer may be provided to adapt the work function of the PMOS transistor device 1. In particular, thickness and Ge concentration may suitably be chosen to properly adapt the work function. For example, the thickness of the channel SiGe alloy layer may be below 100 nm, particularly below 50 nm.

The configuration shown in FIG. 1a further comprises a dielectric layer 30, for example, a high-k layer, formed on the substrate 3 and the sidewalls of the gate electrodes 11 and 21. Moreover, the PMOS transistor device 1 comprises sidewall spacers 14 and the NMOS transistor device 2 comprises sidewall spacers 24 as well. The sidewall spacers 12 and 24 may, in principle, be formed of a silicon nitride material. It goes without saying that a huge plurality of PMOS and NMOS transistor devices 1 and 2 are formed on a wafer.

The configuration shown in FIG. 1a may be manufactured according to the following process flow. A trench may be formed in the substrate 3 and filled with some oxide material. The oxide material is also formed (as a pad oxide) on the surface of the substrate. A mask may be formed on the region of the substrate 3 where the PMOS device 1 of FIG. 1a is to be formed and P-well implantation is performed in the region of the substrate 3 where the NMOS device 2 of FIG. 1a is to be formed. After removal of the mask, another mask layer is formed and patterned to cover the region where the P-well implantation was performed and exposes the region of the substrate 3 where the PMOS device 1 of FIG. 1a is to be formed. N-well implantation is, subsequently, performed in that region.

A (nitride) mask layer may be formed, subsequently, on the pad oxide and patterned to cover the P-well region while exposing the N-well region of the substrate. The pad oxide is removed from the N-well region and, then, a channel SiGe alloy layer may be formed in the N-well region on the exposed substrate.

Then, another mask may be formed on the channel SiGe alloy layer to protect the same during a process of removing the patterned (nitride) mask layer and pad oxide from the substrate above the P-well region. After oxide re-growth on the entire intermediate structure comprising the channel SiGe alloy layer, in the context of an exemplary HKMG procedure, hafnium oxide HfOₓ or a different high-k material (for example, with a permittivity k of more than 30) is formed on the entire intermediate structure. Subsequently, a metal layer may be deposited and (after appropriate masking) etched away above the P-well region only. Another metal layer may, subsequently, be formed on the P-well region to provide a metal gate layer 21 of NMOS transistor device 2 of FIG. 1a, for instance. An example for a resulting structure is shown in FIG. 2. In the PMOS region of the substrate 3, as separated from the NMOS region by STI 4, a channel SiGe alloy layer 1000, oxide layer 1010, high-k dielectric layer 1020 (for example k larger than 25) and metal layer 1030 are formed. In the NMOS region, the substrate 3 is covered by the stack comprising the oxide layer 1010, the high-k layer 1020 and a metal layer 1040.

A polysilicon layer may be formed atop of the metal gate layers 1030 and 1040 or in place of the same to provide the gate electrode 11 of the PMOS transistor 1 and gate electrode 21 of the NMOS transistor device 2 of FIG. 1a, in principle.

After deposition and appropriate etching of a nitride layer for providing the cap layers 12 and 23 shown in FIG. 1a, a dielectric layer may be formed and appropriately etched and a spacer layer may be formed and appropriately etched in order to provide the dielectric layer 30 and sidewall spacers 14 and 24 of FIG. 1a, respectively.

It is to be understood that a process wafer comprises a huge plurality of the NMOS and PMOS transistor devices that are exemplarily shown in FIG. 1a. These devices are to be designed for different kinds of operations. In particular, some of the PMOS transistor devices 1 are to be produced as low, standard or high voltage threshold devices, whereas other ones are to be produced as super high voltage threshold devices.

An implant mask layer may be formed on the wafer and it is patterned to achieve a mask 40 that covers the NMOS transistor device 2 and exposes PMOS transistor devices 1 that are not designed as super high voltage threshold devices, as shown in FIG. 1b. An ion implantation process 100 is performed in order to form source/drain junctions and extensions and halos for the PMOS transistor device. The gate cap 13 protects the gate electrode 11 from counter-doping during the source/drain implantation processes. The halo implant is intended to suppress sub-surface leakage currents.

Implantation processes 100 may provide implants for low voltage threshold devices. After completion of the implantation process 100, the mask 40 is removed and another mask is formed covering NMOS devices 2 and PMOS devices 1 that are not to be subjected to the following implantation process. The following implantation process provides for standard voltage threshold devices, for example. After completion of that implantation process, the implantation mask used in that process is removed and another mask is formed covering NMOS devices 2 and PMOS devices 1 that are not to be subjected to the following implantation process. The following implantation process provides for high voltage threshold devices, for example. Implants for forming the source/drain junctions may comprise carbon ions with a density of some 10¹⁴ cm⁻³. Implantation energy may be in a range of 5-10 keV, in particular, 7 keV. For the source/drain extensions with a density of about 10¹⁵ cm⁻³, an implantation energy of about 25 keV (low voltage threshold) or 3 keV (standard voltage threshold) may be used. The halos may be formed by As with a density of some 10¹³ cm⁻³, for example, implanted at energies of about 40 keV. Tilted implantation of the halo regions with an angle measured from the surface of the substrate of about 30° may be performed.

However, no super high voltage threshold implantation is performed before the following anneal processing. After completion of the above-described implantation processes, the implantation mask used in the latest implantation process is removed and the wafer is subjected to anneal treatment 200 (see FIG. 1c) in order to stabilize and activate the dopants implanted in the preceding implantation process (for example, for achieving low, standard and high voltage threshold devices). For example, ultra-fast anneal with a peak temperature around 1230° C. and an anneal time of about 0.8 ms may be performed.

After completion of the anneal process 200, dopants forming source/drain regions, extensions and halos of low, standard and high voltage threshold devices are stabilized and/or activated. No implantation processing for obtaining super high voltage threshold devices has been performed yet. Contrary to the art, implantation of dopants forming source/drain regions, extensions and halos of super high voltage threshold PMOS transistor devices is only performed after completion of the anneal process 200. Thus, as illustrated in FIG. 1d, after completion of the anneal process 200 shown in FIG. 1c, an implant mask 50 is formed over the NMOS device 2 and PMOS devices that are already finished with respect to source/drain features. The implant mask 50 exposes PMOS devices 1 that are designed as super high voltage threshold devices, one of which is exemplarily shown in FIG. 1d. After formation of the protecting implant mask 50, an implantation process 300 is carried out in order to form source/drain regions, extensions and halos of super high voltage threshold PMOS devices 1. Implants for forming the source/drain junctions may comprise carbon ions with a density of some cm⁻³, for example, 3×10¹⁴. Implantation energy may be in a range of 6-8 keV, in particular 7 keV. For the source/drain extensions with a density of about 10¹⁵ cm⁻³, an implantation energy of about 3 keV may be used. The halos may be formed by As with a density of some 10¹³ cm⁻³, 4×10¹³ cm⁻³, for example, implanted at energies of about 40 keV. Tilted implantation of the halo regions with an angle measured from the surface of the substrate of about 30° may be performed. It is noted that activation anneal for the dopants may be performed after NMOS implant is done.

In the following the reference sign 1 denotes the low leakage super high voltage threshold PMOS transistor device obtained by the implantation process illustrated in FIG. 1d.

As a next step, a nitride layer 60 is formed over the entire structure in the described example, as shown in FIG. 1e. The nitride layer 60 at least partially protects the cap layer 13 against removal during the following step of etching a cavity at both sides of the gate electrode 11 (channel) of the PMOS transistor device 1. The cavity is etched in the presence of an etching mask protecting the NMOS device 2 against etching (see FIG. 1f).

As shown in FIG. 1f, the cavity is filled with a stressed material 80, for example, stressed SiGe material. The compressively strained silicon/germanium mixture may be embedded in the drain and source region on the basis of selective epitaxial growth techniques, ion implantation and the like, while using well-established process recipes, wherein raised drain and source configurations in which a silicon/germanium mixture may be provided above the strained silicon layer, a substantially planar configuration with embedded silicon/germanium material in the drain and source regions, and any combinations thereof, may be efficiently provided. An appropriate germanium concentration may readily be selected by determining the initial strain level of the silicon-based semiconductor layer, which in some illustrative embodiments may be provided in the form of a strained silicon layer in an SOI configuration. Furthermore, the germanium concentration may be adjusted in a highly local manner, thereby providing a high degree of flexibility in individually adapting the performance of the low leakage super high voltage threshold PMOS transistor device 1. By selecting appropriate parameter values a high degree of intrinsic stress, such as up to 2 Gigapascal (GPa) and even more of compressive stress may be created so as to significantly enhance the mobility of charge carrier in the channel region of the PMOS transistor device 1.

After the formation of the embedded SiGe, the PMOS transistor device 1 may be covered by an etch mask and the nitride layer 60 may be etched in the NMOS region. The cap layers 13 and 23 might then be removed and an implantation sequence for the NMOS transistor device 2 might be started.

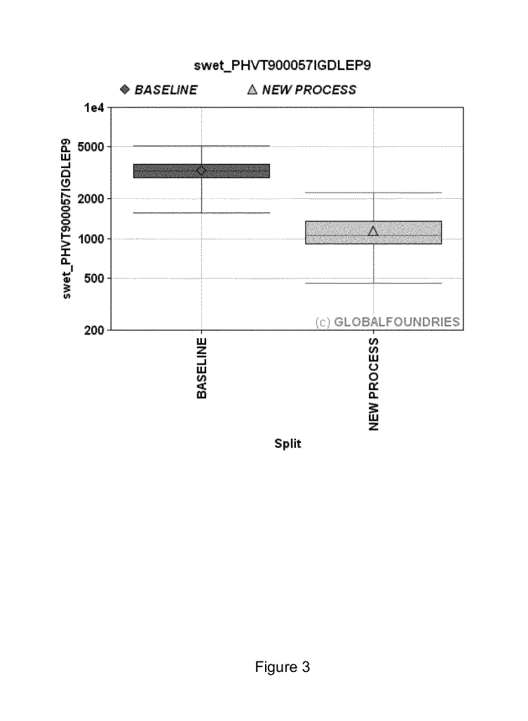

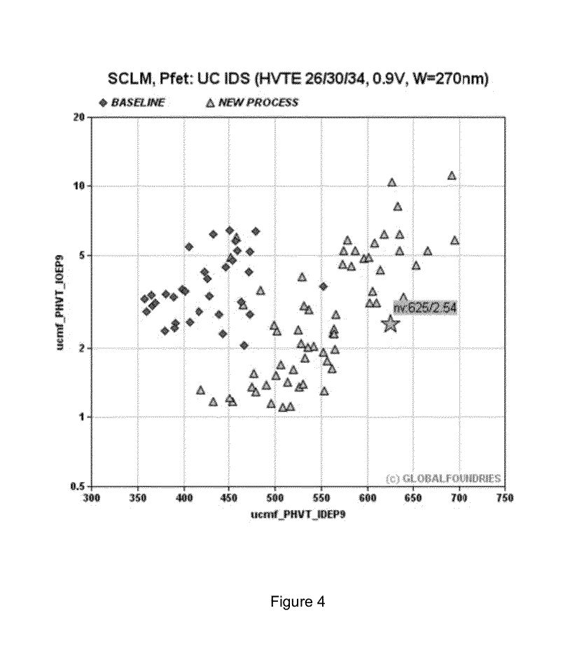

As described above, super high voltage threshold dopants are only implanted after thermal anneal for stabilizing and activating dopants generating source/drain features for devices other than super high voltage threshold PMOS transistor devices were completed. In other words, the steps of rapid thermal anneal and implantation of super high voltage threshold dopants is reversed as compared to the art. This inventive approach results in significantly reduced GIDL as compared to the art, as shown in FIG. 3. The experimental results shown in FIG. 3 prove that GIDL for the inventive process (indicated as NEW PROCESS in FIG. 3) is reduced by a factor of about 3 as compared to the standard process (indicated as BASE LINE in FIG. 3). Moreover, leakage currents are reduced, as can be seen from the experimental results illustrated in FIG. 4. In FIG. 4, the ordinate indicates the leakage current in nA/μm and the abscissa indicates saturation current in μA/μm. The star indicates the target value that is to be approached as close as possible. Experimental results for the inventive sequence of processing steps are indicated by the triangles, whereas squares indicate experimental results achieved for the standard sequence known in the art. Leakage reduction by a factor of about 3 may be achieved.

As a result, the present disclosure provides manufacturing techniques for semiconductor devices comprising super high voltage threshold PMOS transistor devices. Particularly, the provided manufacturing techniques include implanting source/drain features of the super high voltage threshold PMOS transistor devices after anneal treatment is carried out for stabilizing and activating dopants previously implanted for transistor devices that are not designed as super high voltage threshold PMOS transistor devices (for example, low or standard voltage threshold PMOS transistor devices). As a consequence, GIDL from which super high voltage threshold PMOS transistor devices suffer heavily may be significantly reduced and leakage currents may be suppressed.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming a semiconductor device, comprising the steps of:
forming first and second PMOS transistor devices, wherein said first PMOS transistor devices are low, standard or high voltage threshold transistor devices and said second PMOS transistor devices are super high voltage threshold transistor devices, wherein:
forming said first PMOS transistor devices comprises implanting dopants to form source and drain junctions of said first PMOS transistor devices and performing a thermal anneal of said first PMOS transistor devices after implanting said dopants; and
forming said second PMOS transistor devices comprises implanting dopants to form source and drain junctions of said second PMOS transistor devices after performing said thermal anneal of said first PMOS transistor devices.

2. The method of claim 1, further comprising forming NMOS transistor devices comprising implanting dopants to form source and drain junctions of said NMOS transistor devices after implanting said dopants to form source and drain junctions of said second PMOS transistor devices.

3. The method of claim 1, wherein forming said second PMOS transistor devices further comprises implanting dopants to form source and drain extensions and halos of said second PMOS transistor devices after performing said anneal of said first PMOS transistor devices.

4. The method of claim 1, wherein forming said first PMOS transistor devices further comprises implanting dopants to form source and drain extensions and halos of said first PMOS transistor devices before performing said anneal of said first PMOS transistor devices.

5. The method of claim 1, wherein forming said first PMOS transistor devices comprises forming gate electrodes of said first PMOS transistor devices over a first region of a semiconductor substrate and forming said second PMOS transistor devices comprises forming gate electrodes of said second PMOS transistor devices over a second region of said semiconductor substrate and further comprising forming an implantation mask over said gate electrodes of said second PMOS transistor devices and said second region before implanting the dopants to form the source and drain junctions of said first PMOS transistor devices.

6. The method of claim 5, wherein forming said NMOS transistor devices comprises forming gate electrodes of said NMOS transistor devices over a third region of said semiconductor substrate wherein the implantation mask is formed over said gate electrodes of said NMOS transistor devices and said third region before implanting the dopants to form the source and drain junctions of said first PMOS transistor devices.

7. The method of claim 5, further comprising forming a mask over said gate electrodes of said second PMOS transistor devices and said second region before performing the thermal anneal of said first PMOS transistor devices.

8. The method of claim 6, further comprising forming a mask over said gate electrodes of said NMOS transistor devices and said third region before performing the thermal anneal of said first PMOS transistor devices.

9. The method of claim 5, further comprising forming sidewall spacers at sidewalls of said gate electrodes of said first and second PMOS transistor devices before implanting the dopants to form source and drain junctions of said first and second PMOS transistor devices.

10. The method of claim 1, wherein forming said second PMOS transistor devices further comprises forming embedded compressively strained material adjacent to gate electrodes of said second PMOS transistor devices.

11. The method of claim 1, wherein forming said second PMOS transistor devices further comprises forming channel SiGe layers below gate electrodes and gate dielectrics of said second PMOS transistor devices.

12. The method of claim 11, wherein said thermal anneal is performed in the temperature range from 1200-1300° C. and for a time period of between 0.5-1 ms.

13. A method of forming a semiconductor device, comprising the steps of:
forming a low, standard or high voltage threshold PMOS transistor device;
forming a super high voltage threshold PMOS transistor device; and
forming an NMOS transistor device separated by an isolation region from said super high voltage threshold PMOS transistor device;
wherein forming said low, standard or high voltage threshold PMOS transistor device comprises forming a first gate electrode over a first region of a semiconductor substrate, implanting first dopants to form source and drain junctions in said first region and performing an anneal treatment to activate said first dopants; and
wherein forming said super high voltage threshold PMOS transistor device comprises forming a second gate electrode over a second region of said semiconductor substrate and implanting second dopants to form source and drain junctions in said second region after completion of said anneal treatment performed to activate said first dopants.

14. The method of claim 13, further comprising implanting dopants to form source and drain extensions and halos in said second region after completion of said anneal treatment performed to activate said first dopants.

15. The method of claim 13, wherein forming said NMOS transistor device comprises forming a third gate electrode of said NMOS transistor device over a third region of said semiconductor substrate, and further comprising forming an implantation mask over said second gate electrode and said second region, as well as over said third gate electrode and said third region, before implanting said first dopants.

16. The method of claim 13, wherein forming said NMOS transistor device comprises forming a third gate electrode of said NMOS transistor over a third region of said semiconductor substrate, and further comprising forming a mask over said second gate electrode and said second region, as well as over said third gate electrode and said third region, before performing said anneal treatment to activate said first dopants.

17. The method of claim 13, wherein forming said super high voltage threshold PMOS transistor device further comprises forming a channel SiGe layer on said second region and a gate dielectric on said channel SiGe layer.

18. The method of claim 17, wherein said thermal anneal is performed in the temperature range from 1200-1300° C. and for a time period of between 0.5-1 ms.
